(19) United States
(12) Patent Application Publication
(10) Pub. No.: US 2003/0185083 A1
(43) Pub. Date: Oct. 2, 2003

(54) Low cost protable memory system

(76) Inventor: Tung-Cheng Kuo, Yilan Hsien (TW)

Correspondence Address: J.C. Patents, Inc., Suite 250, 4 Venture, Irvine, CA, 92618, US

(21) Appl. No.: 10/112,309

(22) Filed: Mar. 27, 2002

(51) Int. Cl. G11C 8/00

(52) U.S. Cl. 365/226

(57) ABSTRACT

A low-cost portable memory system includes at least a volatile memory device in conjunction with a micro power supply. Since the volatile memory technology is fully developed, it is readily be applied to a portable memory system to provide a low cost memory system, especially in the case for a short period memory storage.

### BACKGROUND OF THE INVENTION

1. Field of the Invention

The present invention relates to a structure of a portable memory system. More particularly, the present invention relates to a structure of a low-cost portable memory system.

2. Background of the Invention

At present, portable memory system are often used by various portable computer systems as well as hand-held electronic devices, such as digital cameras, palmtops, Personal Digital Assistants (PDAs), digital music players, or cellular phones for storing and transporting vital information. This is the reason flash memory has quickly become one of the hottest portable storage technologies. Flash memory is ideal for dozens of portable applications. It is more flexible than a floppy and is faster than a hard drive. A flash storage is more rugged, which is able to tolerate severe shock and vibration without losing data. A flash storage card is also designed with solid state components, which save power and consume less energy. Furthermore, in one way or another, all flash memories are some varieties of an electrically erasable programmable ROM (EEPROM) chip that maintains its content unchanged even when power is interrupted. Flash memory, however, is expensive, a dollar a megabyte as oppose to pennies a megabyte for most optical and magnetic forms of storage.

### SUMMARY OF THE INVENTION

Accordingly, the present invention provides a portable memory system, wherein a low cost memory device is used.

The present invention also provides a portable memory device, wherein a low cost volatile memory device, such as a DRAM (dynamic random access memory) or a SRAM (static random access memory) device, in conjunction with a micro power supply is used to replace the expensive flash memory in the portable memory device.

Since the DRAM device and the SRAM device are relatively inexpensive and the RAM technology is fully developed, they are readily be adopted in a portable memory system to provide a low cost memory system, especially in the case for a short period storage.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is schematic diagram illustrating the portable memory system of the present invention.

### DESCRIPTION OF THE PREFERRED EMBODIMENTS

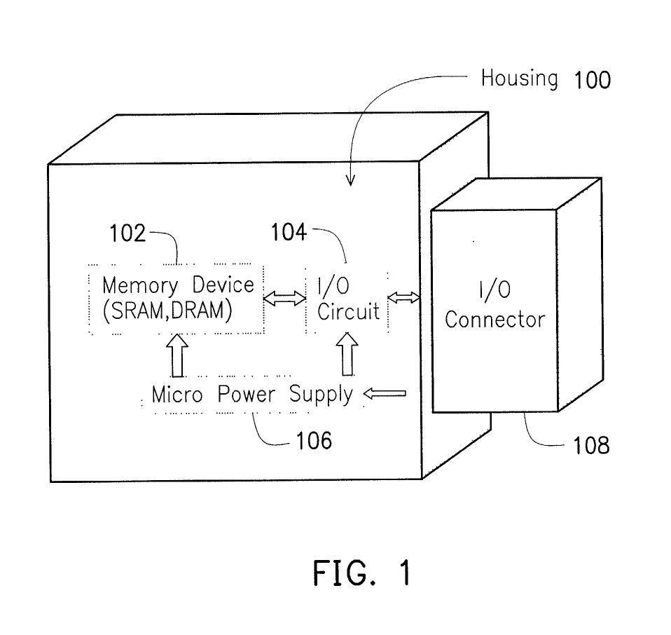

FIG. 1 is a schematic diagram illustrating the portable memory system of the present invention.

The portable memory system of the present invention includes the memory cards that are usually used in digital cameras, music players, cellular phones, PDAs, etc. Referring to FIG. 1, the portable memory system includes a housing unit 100 that contains at least a volatile memory device 102, such as a SRAM or a DRAM device, an input/output (I/O) circuit 104 and a micro power supply unit 106. The I/O circuit 104 in the housing unit 100 is used to switch the memory device 102 to an “on” state or an “off” state and to transmit data to and from the memory device 102. The micro power supply unit 106, for example, a rechargeable battery, is used to provide the memory device 102 and the I/O circuit 104 with electrical power.

As shown in FIG. 1, the memory device 102 is connected to the micro power supply unit 106, so that power is continuously supplied to the memory device 102, for example, for refreshing the memory device 102 at periodic intervals or for maintaining a given memory logic state in the memory device 102. Data is thus retained in the memory device 102 during the lifetime of the micro power supply unit 106 or before the micro power supply unit 106 is recharged. Additionally, the same micro power supply unit 106 is connected to the I/O circuit 104 to provide power to the I/O circuit 104. The memory device 102 is also connected to the I/O circuit 104, which in turn is connected to an I/O connector unit 108. The I/O connector unit 108 is an interface device and is configured to couple the memory system with a memory reading device and to communicate information therebetween. The I/O connector unit includes contact areas, which match with those on the existing memory reading devices to provide, for example, communication signal path and electrical power to the memory system.

In comparison, the present RAM, either a SRAM device or a DRAM device, is relatively fast and relatively cheap to fabricate in large quantity, for example, at least two to three times less expensive than a typical flash memory. Adopting a SRAM device or a DRAM device in conjunction with a micro power supply to provide at least a short-term memory storage, significantly reduces the cost of a portable memory device. Moreover, the technologies for DRAM and SRAM are fully established. As a result, they are readily applicable in a portable memory system.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A portable memory system, comprising:
a random access memory (RAM) device;
a micro power supply unit to supply an electrical power to the memory device; and
an input/output (I/O) circuit to transmit data to and from the memory device.

2. The system of claim 1, wherein the system further comprises an I/O connector to communicate information between the portable memory device and an memory reading device.

3. The system of claim 1, wherein the micro power supply unit also provides the electrical power to the input/out circuit.

4. The system of claim 1, wherein the memory device includes a DRAM device or a SRAM device.

5. The system of claim 1, wherein the micro power supply unit includes a rechargeable battery.

6. The system of claim 1, wherein the memory device, the micro power supply unit and the input/output circuit are contained inside a housing unit.

7. A portable memory system, comprising:
a volatile memory module having an internal power supply for supplying an internal electrical power and an interface device for connecting to a memory reading device.

8. The system of claim 7, wherein the internal power is rechargeable.

9. The system of claim 7, wherein the interface device includes contact areas, which match with those on the memory reading device to provide a communication signal path to the memory system.

10. The system of claim 7, wherein the interface device includes contact areas, which match with those on the memory reading device to provide an external electrical power to the memory system.

11. A portable memory system, comprising:
a volatile memory module having an internal power supply for supplying an internal electrical power;
an input/output (I/O) circuit to transmit data to and from the memory module; and
an interface device for connecting to a memory reading device.

12. The system of claim 11, wherein the internal power supply is rechargeable.

13. The system of claim 11, wherein the interface device includes contact areas which match with those on the memory reading device to provide a communication signal path to the memory system.

14. The system of claim 11, wherein the interface device includes contact areas, which match with those on the memory reading device to provide an external electrical power to the memory system.
